(19) United States
(12) Patent Application Publication
(10) Pub. No.: US 2026/0194604 A1
(43) Pub. Date: Jul. 9, 2026

(54) MAGNETIC DETECTION SYSTEM

(71) Applicant: HAMAMATSU PHOTONICS K.K., Hamamatsu-shi (JP)

(72) Inventors: Takeshi ENDO, Shizuoka (JP); Daisuke MATSUO, Shizuoka (JP); Natsuki EJIRI, Shizuoka (JP)

(73) Assignee: HAMAMATSU PHOTONICS K.K., Hamamatsu-shi (JP)

(21) Appl. No.: 19/440,926

(22) Filed: Jan. 6, 2026

(30) Foreign Application Priority Data
Jan. 7, 2025 (JP) 2025-002320

(51) Int. Cl. G01R 33/00

(52) U.S. Cl. CPC G01R 33/0029

(57) ABSTRACT

A magnetic detection system comprises: a cell in which an alkali metal is sealed; a laser light source; a light detection unit configured to generate a light detection signal; a coil configured to apply a magnetic field in a predetermined direction inside the cell; and first and second magnetic sensor modules each having a control unit configured to supply a modulation signal to the coil, execute digital processing on a magnetic-field detection signal output from the light detection unit using a digital signal for demodulation, and generate a digital processing signal indicating a magnetic-field intensity inside the cell, wherein the control unit of the second magnetic sensor module shares the modulation signal supplied from the first magnetic sensor module to supply the modulation signal to the coil, and uses a signal obtained by performing A/D conversion on the modulation signal as the digital signal for demodulation.

### TECHNICAL FIELD

An aspect of an embodiment relates to a magnetic detection system.

### BACKGROUND

Conventionally, detection devices having a plurality of magnetic sensors have been used. For example, as disclosed in the following Patent Literature 1, a magnetic field detection device includes a plurality of magnetometer probes and a control device and the control device synchronously controls the plurality of magnetometer probes so that the plurality of magnetometer probes generate modulated magnetic fields with the same frequency and phase by means of modulated currents.

Patent Literature 1: Chinese Unexamined Patent Publication No. 113093065

### SUMMARY

In the conventional devices as described above, digital processing signals may be generated by demodulating detection signals from a plurality of magnetic sensors using digital signals for demodulation. In this case, intensities of the digital processing signals tend to be unstable due to a phase difference between detection signals from some magnetic sensors and digital signals for demodulation.

Therefore, an aspect of an embodiment has been made in view of the above issue, and an objective thereof is to provide a magnetic detection system capable of stabilizing the intensities of a plurality of digital processing signals generated from a plurality of detection signals output from a plurality of magnetic sensors.

According to an aspect of an embodiment, there is provided a magnetic detection system comprising: a cell in which an alkali metal is sealed; a laser light source configured to emit laser light toward an inside of the cell; a light detection unit configured to detect the laser light having passed through the inner side of the cell and generate a light detection signal; a coil configured to apply a magnetic field in a predetermined direction inside the cell; and first and second magnetic sensor modules each having a control unit configured to supply a modulation signal having a modulation frequency to the coil, execute digital processing on a magnetic-field detection signal generated based on the light detection signal output from the light detection unit using a digital signal for demodulation corresponding to the modulation frequency, and generate a digital processing signal indicating a magnetic-field intensity inside the cell, wherein the control unit of the second magnetic sensor module shares the modulation signal supplied from the control unit of the first magnetic sensor module to supply the modulation signal to the coil, and uses a signal obtained by performing A/D conversion on the modulation signal supplied by the control unit of the first magnetic sensor module as the digital signal for demodulation.

According to the above-described aspect, in each of the first and second magnetic sensor modules, a magnetic field having a modulation frequency is applied in a predetermined direction within the cell by means of the coil, and digital processing is performed on the magnetic field detection signal generated based on the light detection signal output from the light detection unit using a digital signal for demodulation, thereby generating a digital processing signal. In this case, in the second magnetic sensor module, the modulation signal supplied to the coil by the first magnetic sensor module is shared, and a signal obtained by performing A/D conversion on the shared modulation signal is used as the digital signal for demodulation. As a result, the modulation frequency of the magnetic field in the second magnetic sensor module matches the modulation frequency of the magnetic field in the first magnetic sensor module, and the repetition frequency of the digital signal for demodulation in the second magnetic sensor module matches the modulation frequency of the magnetic field. As a result, the occurrence of beat signals between the two magnetic field detection signals output from the first and second magnetic sensor modules is reduced, and variations in the intensities of the two digital processing signals generated from the two magnetic field detection signals are also prevented. As a result, the intensities of the two digital processing signals generated in the two magnetic sensor modules can be stabilized.

### BRIEF DESCRIPTION OF THE DRAWINGS

FIG. 1 is a schematic configuration diagram of a magnetic detection system 101 according to an embodiment.

FIG. 2 is a schematic configuration diagram of a first magnetic sensor module and a second magnetic sensor module of FIG. 1.

FIG. 3 is a block diagram showing a configuration of drive boards 105A and 105B of FIG. 1 in detail.

FIG. 4 is a diagram showing waveforms of modulation signals before and after a conversion process of an ADC 109A of FIG. 3.

FIGS. 5A, 5B, and 5C are graphs showing frequency distributions of various signals processed by a sensor unit 103A of FIG. 3.

FIGS. 6A, 6B, and 6C are graphs showing frequency distributions of various signals that are mixing processing targets of an FPGA 107A of FIG. 3.

FIG. 7 is a flowchart showing a processing flow from driving of the sensor unit 103A to a mixing process in relation to the drive board 105A of FIG. 3.

FIG. 8 is a flowchart showing a flow of a delay decision process of the drive board 105A of FIG. 3 in detail.

### DETAILED DESCRIPTION

Embodiments of the present invention will be described in detail below with reference to the accompanying drawings. Also, in the description, the same reference signs denote the same elements and elements having the same functions, and redundant description thereof will be omitted.

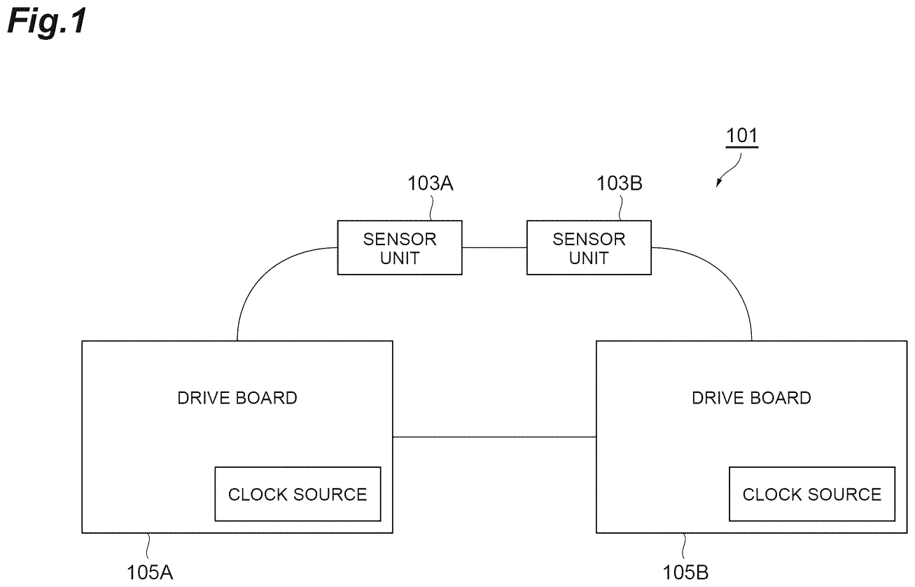

FIG. 1 is a schematic configuration diagram of a magnetic detection system 101 according to the embodiment. The magnetic detection system 101 may be used for the purpose of biological measurement using a magnetoencephalograph (MEG), a magnetospinogram (MSG), or the like or the purpose of material analysis using nuclear magnetic resonance (NMR) or the like, but the purpose of use is not limited thereto.

The magnetic detection system 101 includes a first magnetic sensor module and a second magnetic sensor module, each of which is an optically pumped magnetometer (OPM). The first magnetic sensor module is configured to include a sensor unit 103A and a drive board 105A that is a control board (control unit) configured to control driving of the sensor unit 103A and process a light detection signal from the sensor unit 103A. The second magnetic sensor module is configured to include a sensor unit 103B and a drive board 105B that is a control board (control unit) configured to control driving of the sensor unit 103B and processes a light detection signal from the sensor unit 103B. The magnetic detection system 101 including two magnetic sensor modules can detect magnetic fields at two locations. However, the magnetic detection system 101 may also include three or more magnetic sensor modules.

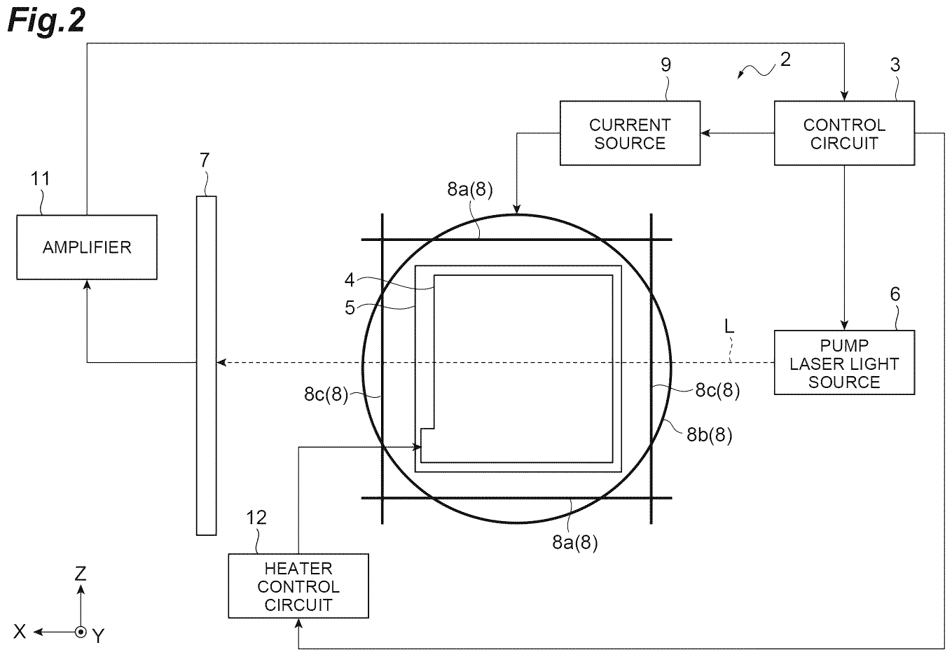

FIG. 2 is a schematic configuration diagram showing the OPM 2 that constitutes each of the first and second magnetic sensor modules. In FIG. 2, the X-axis is defined along an incidence direction of pump light for a cell to be described below, the Y-axis is defined in a direction perpendicular to the X-axis, and the Z-axis is defined in a direction perpendicular to both the X-axis and the Y-axis. The OPM 2 includes a control circuit 3, a cell 4, a heater 5, a pump laser light source (laser light source) 6, a photodiode (light detection unit) 7, a magnetic-field correction unit 8, a current source 9, an amplifier 11, and a heater control circuit 12. In addition, the control circuit 3 corresponds to the drive boards 105A and 105B.

The cell 4 has, for example, a substantially rectangular-parallelepiped and bottomed cylindrical shape, and is formed of a material that has light transmission with respect to pump light L to be described below. Examples of the material of the cell 4 include quartz, sapphire, silicon, Kovar glass, borosilicate glass, and the like. The cell 4 accommodates an alkali metal and a fill gas. The alkali metal sealed in the cell 4 may include at least one of lithium (Li), sodium (Na), potassium (K), rubidium (Rb), and cesium (Cs). The fill gas protects the alkali metal vapor and suppresses noisy light emission. The fill gas may be, for example, at least one inert gas such as helium (He), neon (Ne), argon (Ar), krypton (Kr), xenon (Xe), or nitrogen (N2).

The heater 5 is provided adjacent to the cell 4 and heats the interior of the cell 4. The heater 5 generates heat in accordance with an electric current supplied from a heater control circuit 12 to be described below. In the heater 5, based on a measurement signal from a temperature sensor (not shown) that measures an internal temperature of the cell 4, the supply current from the heater control circuit 12 is controlled so that the internal temperature of the cell 4 reaches a predetermined temperature (e.g., 180° C.), such that the alkali metal is vaporized within the cell 4 and a vapor density is controlled.

The pump laser light source 6 emits the pump light L (laser light) toward the interior of the cell 4 along the X-axis direction. The pump laser light source 6 emits the pump light L, which excites the atoms of the alkali metal, in a circularly polarized state. The pump laser light source 6 may shape the pump light L to any desired size. The atoms of the alkali metal accommodated in the cell 4 are excited by the pump light L. A wavelength of the pump light L is set in accordance with a type of atom (more specifically, an absorption line wavelength of an atom constituting the vapor of the alkali metal), and, for example, is set to match an absorption wavelength of the alkali. In the present embodiment, a drive condition of the pump laser light source 6 is determined by the control circuit 3 that is the drive board 105A or the drive board 105B, and a wavelength of the pump light L emitted from the pump laser light source 6 can be adjusted to match the absorption wavelength of the alkali metal by a control process of the control circuit 3. To implement this control, the pump laser light source 6 has a wavelength control function, for example, a function for controlling the oscillation wavelength using an external resonator, or a configuration for controlling the oscillation wavelength by controlling a temperature of a laser element.

The photodiode 7 is a detection unit that detects the pump light L having passed through the inside of the cell 4 outside the cell 4. The pump light L having passed through the inside of the cell 4 is incident on the photodiode 7. The photodiode 7 generates and outputs a light detection signal corresponding to the intensity of the pump light L. The amplifier 11 amplifies the light detection signal output by the photodiode 7. The amplifier 11 outputs the amplified light detection signal to the control circuit 3.

The magnetic-field correction unit 8 corrects the magnetic field inside the cell 4. Specifically, the magnetic-field correction unit 8 is a set of coils provided around the cell 4 and configured to correct and cancel an environmental magnetic field, such as geomagnetism, in a space where the cell 4 is located, in three axis directions such as X-, Y-, and Z-axis directions. The magnetic-field correction unit 8 includes, for example, a first correction coil 8a wound around the X-axis direction (first direction), a second correction coil 8b wound around the Y-axis direction (second direction), and a third correction coil 8c wound around the Z-axis direction (third direction). The first correction coil 8a, the second correction coil 8b, and the third correction coil 8c generate a first corrective magnetic field along the X-axis direction, a second corrective magnetic field along the Y-axis direction, and a third corrective magnetic field along the Z-axis direction using an electric current supplied from a current source 9, respectively, and apply each magnetic field within the cell 4. The magnetic-field correction unit 8 operates to cancel the environmental magnetic fields in a space where the cell 4 is located, by controlling electric currents to be supplied to the first, second, and third correction coils 8a, 8b, and 8c from the current source 9 under control of the control circuit 3.

Moreover, either the second correction coil 8b or the third correction coil 8c of the magnetic-field correction unit 8 also has the function of superimposing a magnetic field modulation signal in the Y-or Z-axis direction based on a modulation signal supplied from the control circuit 3. Thereby, the control circuit 3 can detect a magnetic field of a predetermined target frequency in the X-axis or Y-axis direction in the space where the cell 4 is located, based on the OPM signal output from the amplifier 11. That is, the OPM signal indicates a change in the transmittance of the pump light L, which reflects a change in the magnetic field intensity.

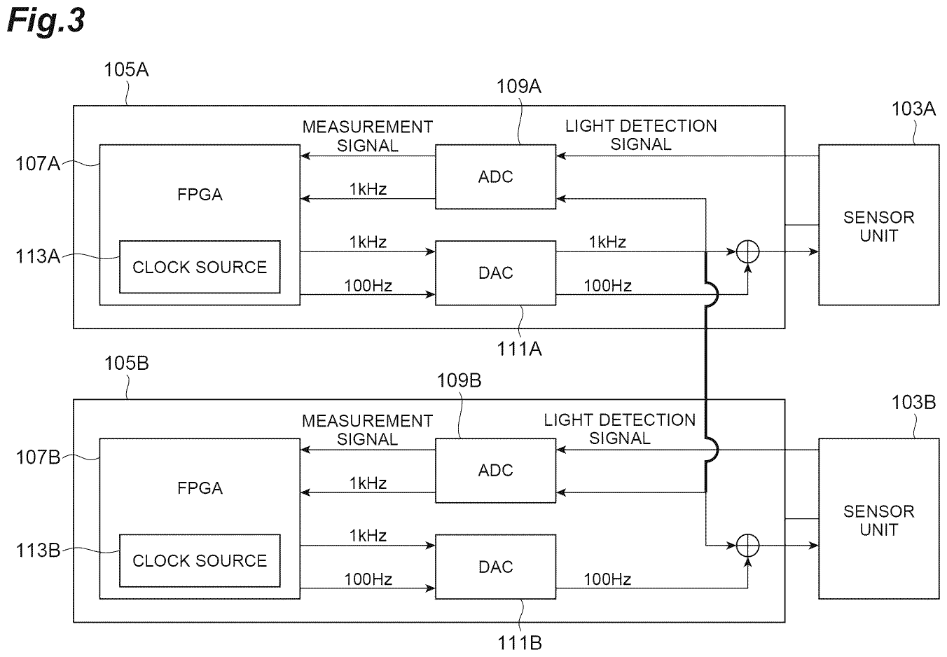

FIG. 3 is a block diagram showing a configuration of the drive boards 105A and 105B in detail. The drive board 105A and the sensor unit 103A are connected to each other by a signal transmission member, for example, a cable, so that analog signals can be transmitted and received therebetween, and the drive board 105B and the sensor unit 103B are connected to each other by a signal transmission member, for example, a cable, so that analog signals can be transmitted and received therebetween. In addition, the drive boards 105A and 105B are connected to each other by a signal transmission member, for example, a cable, so that a drive signal that is an analog signal can be transmitted therebetween. The configurations of the drive boards 105A and 105B will be described below.

The drive board 105A includes a field programmable gate array (FPGA) 107A serving as an arithmetic circuit, an ADC 109A serving as an A/D converter, and a DAC 111A serving as a D/A converter.

The FPGA 107A has a built-in clock source 113A and generates a digital signal of a predetermined frequency using a clock generated by the clock source 113A. Specifically, the FPGA 107A generates a modulation signal that is a sine wave having a modulation frequency of, for example, 1 kHz, as a digital signal for driving the sensor unit 103A. Moreover, during a delay decision process to be described below, the FPGA 107A generates a reference signal, which is a sine wave having a frequency of, for example, 100 Hz, corresponding to the target frequency of a magnetic field intensity measurement target. In addition, the FPGA 107A has a function of a mixing process and a function of a delay decision process (details will be described below).

The DAC 111A performs D/A conversion on the modulation signal generated by the FPGA 107A to generate a modulation signal that is an analog signal. Moreover, The DAC 111A performs D/A conversion on the reference signal generated by the FPGA 107A to generate a reference signal that is an analog signal. The modulation signal and the reference signal generated by the DAC 111A are superimposed to form a superimposed signal, and this superimposed signal is supplied to the sensor unit 103A via the cable. Based on the modulation signal and the reference signal supplied to the sensor unit 103A, the magnetic-field modulation signal is generated by the magnetic-field correction unit 8 of the sensor unit 103A.

The ADC 109A receives a light detection signal from the sensor unit 103A via the cable, performs A/D conversion on the light detection signal, and generates a digital measurement signal. Also, the ADC 109A outputs the generated measurement signal to the FPGA 107A. In addition, the ADC 109A receives the modulation signal output from the DAC 111A, performs A/D conversion on the modulation signal to generate a modulation signal that is a digital signal, further shapes the generated modulation signal into a rectangular wave, and generates a digital signal for demodulation. Also, the ADC 109A outputs the generated digital signal for demodulation to the FPGA 107A.

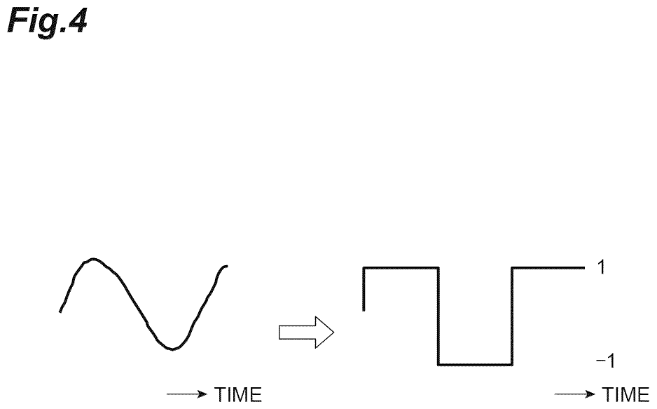

FIG. 4 shows waveforms of modulation signals before and after a conversion process of the ADC 109A. The ADC 109A shapes a modulation signal that periodically increases and decreases at 1 kHz into a rectangular wave by setting a signal value in a time range in which the signal has a positive value with respect to a mean value of the modulation signals to “+1” and setting a signal value in a time range in which the signal has a negative value with respect to a mean value of the modulation signals to “−1.” The modulation signal converted into such a rectangular wave becomes a signal in which noise originating from the modulation frequency after the A/D conversion is reduced.

Here, details of the function of the mixing process and the function of the delay decision process of the FPGA 107A will be described.

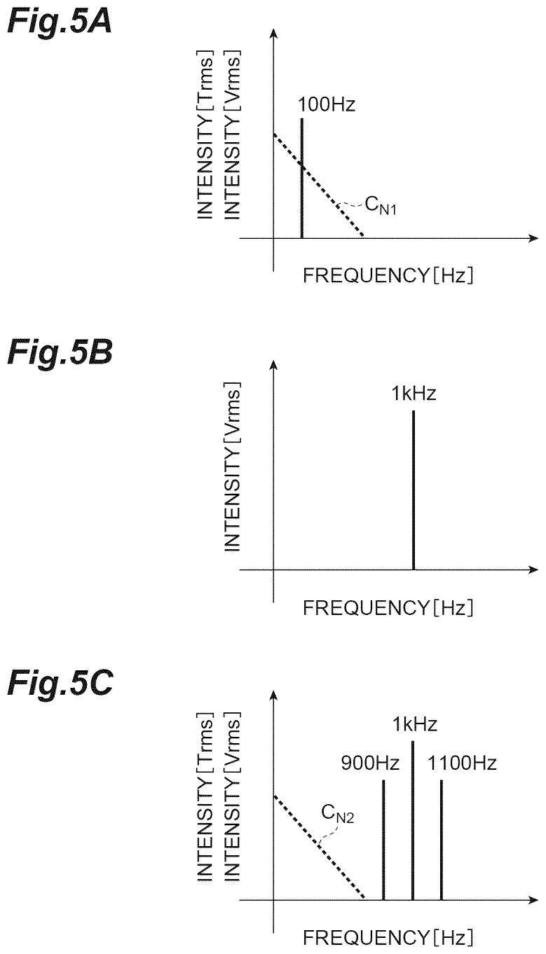

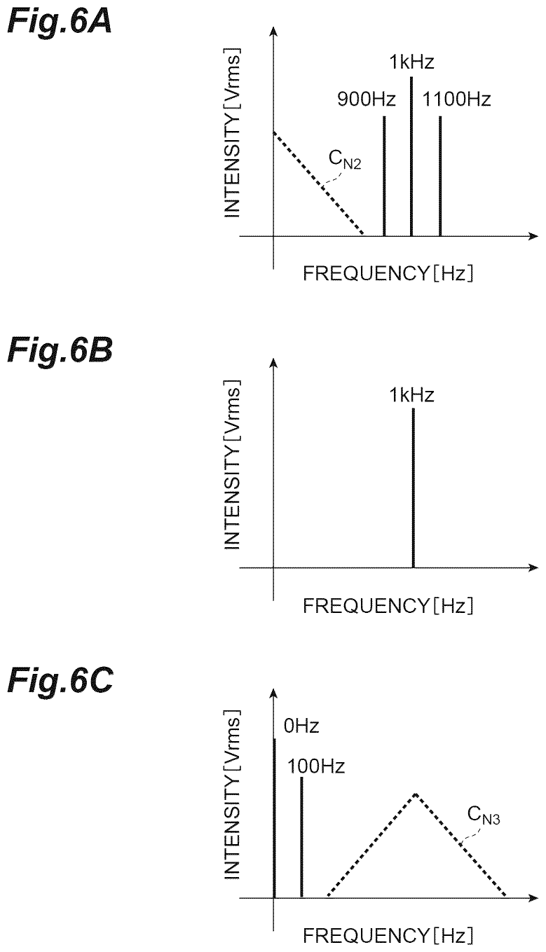

FIGS. 5A, 5B, and 5C are graphs showing frequency distributions of various signals processed by the sensor unit 103A, wherein FIG. 5A is a graph showing a measurement signal that is a measurement target, FIG. 5B is a graph showing a magnetic-field modulation signal, and FIG. 5C is a graph showing a magnetic-field detection signal. FIGS. 6A, 6B, and 6C are graphs showing frequency distributions of various signals that are targets of the mixing process of the FPGA 107A, wherein FIG. 6A is a graph showing the magnetic-field detection signal (identical to that of FIG. 5C), FIG. 6B is a graph showing the digital signal for demodulation, and FIG. 6C is a graph showing a digital processing signal.

First, the function of the mixing process will be described. The measurement signal (FIG. 5A), obtained by performing a digital process on the light detection signal from the sensor unit 103A, includes a frequency component of the target frequency of 100 Hz and a noise component CN₁ originating from the OPM and a magnetic-field modulation signal (FIG. 5B) having a modulation frequency of 1 kHz is superimposed thereon. As a result, the generated magnetic-field detection signal (FIG. 5C) includes a component of a modulation frequency of 1 kHz, components of both sideband components of 900 Hz and 1100 Hz corresponding to a magnitude of the measurement signal, and a noise component CN₂ corresponding to the noise component CN₁. The FPGA 107A generates a digital processing signal (FIG. 6C) indicating the magnetic field intensity inside the cell 4 by performing a mixing process (digital processing) on the magnetic-field detection signal (FIG. 6A) using the digital signal for demodulation (FIG. 6B). The digital processing signal includes a frequency component of 0 Hz corresponding to the modulation signal, a component of a target frequency 100 Hz corresponding to the magnitude of the measurement signal, and a noise component CN₃ in which the noise component CN₂ is folded back at the boundary of 1 kHz. By extracting the target frequency component from this digital processing signal, the magnetic field intensity inside the cell 4 can be detected.

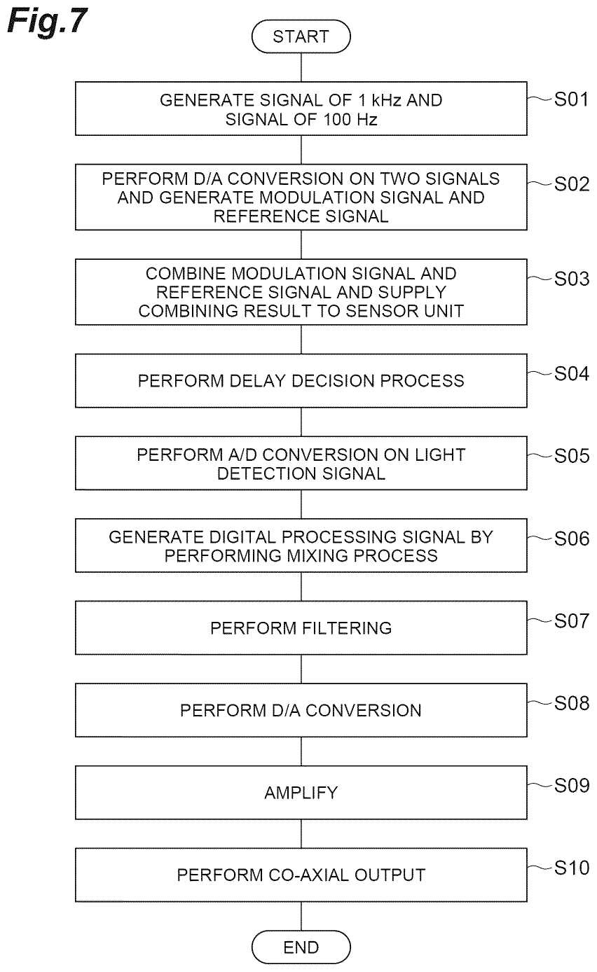

FIG. 7 is a flowchart showing a processing flow from the driving of the sensor unit 103A to the mixing process in relation to the drive board 105A. First, the FPGA 107A generates a modulation signal having a modulation frequency of 1 kHz and a reference signal having a target frequency of 100 Hz (step S01). Also, the DAC 111A performs D/A conversion on the modulation signal and the reference signal to generate a modulation signal and a reference signal that are analog signals (step S02), combines the generated modulation signal and the reference signal, and supplies a combined signal to the sensor unit 103A (step S03). Thereafter, the delay decision process is performed inside the drive board 105A (step S04).

Subsequently, the ADC 109A performs A/D conversion on a light detection signal output from the sensor unit 103A in a state in which only the modulation signal from the DAC 111A is supplied to the sensor unit 103A to generate a measurement signal (step S05). Subsequently, the FPGA 107A executes a mixing process on the magnetic-field detection signal generated from the measurement signal using the digital signal for demodulation in which a delay has been set by the delay decision process and generates a digital processing signal (step S06). Furthermore, the FPGA 107A filters the target frequency component of the digital processing signal and outputs a filtering result to the DAC 111A (step S07). Also, the DAC 111A performs D/A conversion on the target frequency component of the digital processing signal and generates an output signal (step S08). Finally, the output signal is amplified by an amplifier (not shown) inside the drive board 105A (step S09) and is output externally via a coaxial cable such as an SMA or BNC cable (step S10).

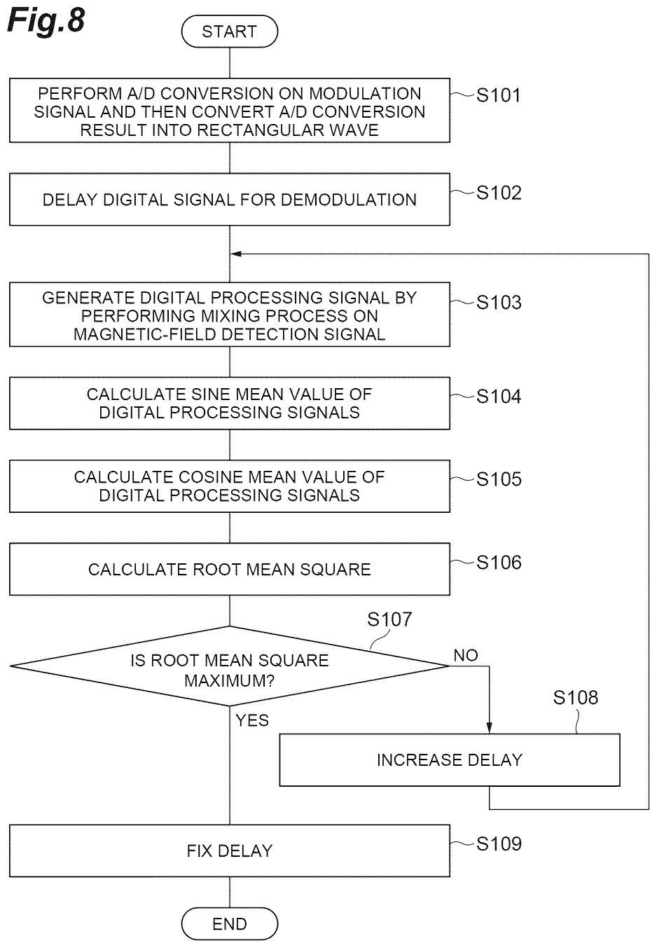

Next, details of the function of the delay decision process will be described. FIG. 8 is a flowchart showing a flow of the delay decision process of the drive board 105A in detail.

First, the ADC 109A performs A/D conversion on a modulation signal output from the DAC 111A and performs conversion into a rectangular wave, thereby generating a digital signal for demodulation (step S101). Subsequently, the FPGA 107A delays the digital signal for demodulation by a minute time x to adjust its phase (step S102). Also, the FPGA 107A generates a digital processing signal by performing the mixing process using the digital signal for demodulation on a magnetic-field detection signal generated based on the light detection signal that is output from the sensor unit 103A in accordance with the supply of the superimposed signal (step S103).

Subsequently, the FPGA 107A extracts the digital processing signal in a predetermined time width, generates a first multiplication signal obtained by multiplying the extracted digital processing signal by a sine-wave signal repeated at a target frequency of 100 Hz, and calculates a mean value of first multiplication signals as a sine mean value (step S104). In addition, the FPGA 107A generates a second multiplication signal obtained by multiplying the extracted digital processing signal by a cosine-wave signal that is a sine-wave signal having a 90-degree phase difference from the above-described sine-wave signal as a signal repeated at a target frequency of 100 Hz and calculates a mean value of second multiplication signals as a cosine mean value (step S105).

Subsequently, the FPGA 107A calculates a root mean square of the sine mean value and the cosine mean value (step S106). This root mean square represents an amplitude of the magnetic field intensity at the target frequency. Also, the FPGA 107A determines whether or not the root mean square has reached its maximum. Specifically, the FPGA 107A determines whether or not the root mean square has changed from an increase to a decrease after a phase adjustment of the current digital signal for demodulation. When a determination result indicates that the root mean square has not yet reached its maximum (step S107; No), the FPGA 107A further delays the digital signal for demodulation by a minute time x (step S108) and returns the process to step S103. On the other hand, when the root mean square has reached its maximum (step S107; Yes), the FPGA 107A fixes the delay time to a delay time obtained by subtracting the minute time x from the delay time of the current digital signal for demodulation (step S109), and ends the delay decision process.

Returning to FIG. 3, the drive board 105B has a configuration similar to that of the drive board 105A and includes an FPGA 107B, an ADC 109B, and a DAC 111B. Like the FPGA 107A, the FPGA 107B has a built-in clock source 113B. The FPGA 107B has functions similar to those of the FPGA 107A, and has the drive function for the sensor unit 103B, the function of the mixing process, and the function of the delay decision process.

The DAC 111B performs D/A conversion on only the reference signal to generate a reference signal that is an analog signal. The ADC 109B receives the modulation signal supplied by the DAC 111A of the FPGA 107A via the cable, performs A/D conversion on the received modulation signal to generate a digital modulation signal, further shapes the generated modulation signal into a rectangular wave, and generates a digital signal for demodulation. Moreover, the drive board 105B is configured so that the modulation signal received by the ADC 109B and the reference signal generated by the DAC 111B are superimposed to generate a superimposed signal, and the superimposed signal is supplied to the sensor unit 103B. Thereby, in the drive board 105B, the modulation signal supplied to the sensor unit 103A by the drive board 105A is shared.

According to the magnetic detection system 101 described above, in each of the sensor units 103A and 103B, a magnetic-field modulation signal having a modulation frequency is applied along a predetermined direction inside the cell 4 by the magnetic-field correction unit 8, and a digital processing signal is generated by performing digital processing on a magnetic-field detection signal generated based on the light detection signal output from the photodiode 7 using the digital signal for demodulation. In this case, in the drive board 105B, the modulation signal supplied to the sensor unit 103A by the drive board 105A is shared, and a signal obtained by performing the A/D conversion on the shared modulation signal is used as the digital signal for demodulation. As a result, the modulation frequency of the magnetic-field modulation signal in the sensor unit 103B matches that in the sensor unit 103A, and the modulation frequency of the modulation signal matches the repetition frequency of the digital signal for demodulation in the drive board 105B. As a result, the occurrence of beat signals in the two magnetic-field detection signals output from the sensor units 103A and 103B is reduced, and fluctuations in the intensities of the two digital processing signals generated from the two magnetic-field detection signals are prevented. That is, continuous phase shifts between the magnetic-field detection signal and the digital signal for demodulation in the mixing process of the drive board 105B are prevented and fluctuations in the intensity of the digital processing signal generated in the drive board 105B are reduced. As a result, the intensities of the two digital processing signals generated in the two magnetic sensor modules can be stabilized.

In the magnetic detection system 101, the modulation signal supplied by the drive board 105A is generated by a clock source within the board. Thereby, in the drive board 105A, the modulation frequency of the magnetic-field modulation signal can easily match the repetition frequency of the digital signal for demodulation, and the intensity of the digital processing signal generated within the drive board 105A can be reliably stabilized.

Moreover, in the magnetic detection system 101, the drive boards 105A and 105B have a function of performing a mixing process on an OPM signal using a digital signal for demodulation. Through such digital processing, a digital processing signal indicating a magnetic-field intensity distribution along a predetermined direction within the cell 4 can be generated from the OPM signal.

Moreover, in the magnetic detection system 101, the drive board 105B uses a signal obtained by performing A/D conversion on the modulation signal supplied from the drive board 105A and then shaping an A/D conversion result into a rectangular wave as a digital signal for demodulation. In this case, in the drive board 105B, noise originating from the modulation frequency due to A/D conversion in the digital processing signal generated by digital processing can be reduced.

Moreover, in the magnetic detection system 101, the drive boards 105A and 105B adjust the phase of the digital signal for demodulation so that the magnetic-field intensity indicated by the digital processing signal becomes large. In this case, in the drive boards 105A and 105B, a phase difference between the modulation signal included in the OPM signal and the digital signal for demodulation is reduced, resulting in the further stabilization of the intensities of the two digital processing signals.

Furthermore, in the magnetic detection system 101, the drive boards 105A and 105B supply a superimposed signal obtained by superimposing a reference signal having a target frequency of the magnetic-field intensity onto the modulation signal to the magnetic-field correction unit 8, and adjust a phase of the digital signal for demodulation based on a digital processing signal obtained in accordance with the superimposed signal. In this way, in the drive boards 105A and 105B, the phase difference between the modulation signal included in the OPM signal and the digital signal for demodulation is reduced, resulting in the further stabilization of the intensities of the two digital processing signals at the target frequency.

Although various embodiments of the present invention have been described above, the present invention is not limited to the above-described embodiments and the present invention may be modified or applied to other things as long as the subject matter described in the claims is not changed.

In the above-described aspect of the embodiment, it is preferable to generate the modulation signal supplied by the control unit of the first magnetic sensor module by a clock source within the control unit. Thereby, in the first magnetic sensor module, the modulation frequency of the magnetic field applied by the coil can easily match the repetition frequency of the digital signal for demodulation, and the intensity of the digital processing signal generated within the first magnetic sensor module can be reliably stabilized.

Moreover, in the above-described aspect, the control units of the first and second magnetic sensor modules also preferably perform a mixing process on a magnetic-field detection signal using the digital signal for demodulation. By executing such digital processing, a digital processing signal indicating the magnetic-field intensity distribution along a predetermined direction within the cell can be generated from the magnetic-field detection signal.

Moreover, in the above-described aspect, it is also preferable that the control unit of the second magnetic sensor module use a signal obtained by performing A/D conversion on the modulation signal supplied from the control unit of the first magnetic sensor module and then shaping an A/D conversion result into a rectangular wave as the digital signal for demodulation. In this case, in the second magnetic sensor module, noise in the digital processing signal generated by digital processing can be reduced.

Moreover, in the above-described aspect, it is also preferable that the control units of the first and second magnetic sensor modules adjust the phase of the digital signal for demodulation so that the magnetic-field intensity indicated by the digital processing signal becomes large. In this case, in the first and second magnetic sensor modules, the phase difference between the modulation signal included in the magnetic-field detection signal and the digital signal for demodulation is reduced, resulting in the further stabilization of the intensities of the two digital processing signals.

Furthermore, in the above-described aspect, it is also preferable that the control units of the first and second magnetic sensor modules calculate a magnetic-field intensity based on two multiplication values obtained by multiplying the digital processing signal by two sine-wave signals having a target frequency of the magnetic-field intensity and having a 90-degree phase difference from each other. In this case, in the first and second magnetic sensor modules, the phase difference between the modulation signal included in the magnetic-field detection signal and the digital signal for demodulation is reduced, resulting in the further stabilization of the intensities of the two digital processing signals at the target frequency.

Furthermore, in the above-described aspect, it is also preferable that the control units of the first and second magnetic sensor modules supply a superimposed signal obtained by superimposing a reference signal having a target frequency of the magnetic-field intensity onto the modulation signal to the coil, and adjust the phase of the digital signal for demodulation based on a digital processing signal obtained in accordance with the superimposed signal. In this way, in the first and second magnetic sensor modules, the phase difference between the modulation signal included in the magnetic-field detection signal and the digital signal for demodulation is reduced, resulting in the further stabilization of the intensities of the two digital processing signals at the target frequency.

A magnetic detection system of an embodiment is [1] “a magnetic detection system including:
a cell in which an alkali metal is sealed;
a laser light source configured to emit laser light toward an inner side of the cell;
a light detection unit configured to detect the laser light having passed through the inner side of the cell and generate a light detection signal;
a coil configured to apply a magnetic field in a predetermined direction inside the cell; and
first and second magnetic sensor modules each having a control unit configured to supply a modulation signal having a modulation frequency to the coil, execute digital processing on a magnetic-field detection signal generated based on the light detection signal output from the light detection unit using a digital signal for demodulation corresponding to the modulation frequency, and generate a digital processing signal indicating a magnetic-field intensity inside the cell,
wherein the control unit of the second magnetic sensor module
shares the modulation signal supplied from the control unit of the first magnetic sensor module to supply the modulation signal to the coil, and
uses a signal obtained by performing A/D conversion on the modulation signal supplied by the control unit of the first magnetic sensor module as the digital signal for demodulation.”

A magnetic detection system of an embodiment may be [2] “the magnetic detection system according to the above-described [1], wherein the modulation signal supplied by the control unit of the first magnetic sensor module is generated by a clock source within the control unit.”

A magnetic detection system of an embodiment may be [3] “the magnetic detection system according to the above-described [1] or [2], wherein control units of the first and second magnetic sensor modules perform a mixing process on the magnetic-field detection signal using the digital signal for demodulation.”

A magnetic detection system of an embodiment may be [4] “the magnetic detection system according to any one of the above-described to [3], wherein the control unit of the second magnetic sensor module uses a signal obtained by performing A/D conversion on the modulation signal supplied by the control unit of the first magnetic sensor module and then shaping an A/D conversion result into a rectangular wave as the digital signal for demodulation.”

A magnetic detection system of an embodiment may be [5] “the magnetic detection system according to any one of the above-described to [4], wherein control units of the first and second magnetic sensor modules adjust a phase of the digital signal for demodulation so that the magnetic-field intensity indicated by the digital processing signal becomes large.”

A magnetic detection system of an embodiment may be [6] “the magnetic detection system according to the above-described [5], wherein the control units of the first and second magnetic sensor modules calculate the magnetic-field intensity based on two multiplication values obtained by multiplying the digital processing signal by two sine-wave signals having a target frequency of the magnetic-field intensity and having phases between which there is a 90-degree difference.”

A magnetic detection system of an embodiment may be [7] “the magnetic detection system according to the above-described [5] or [6], wherein the control units of the first and second magnetic sensor modules supply a superimposed signal obtained by superimposing a reference signal having a target frequency of the magnetic-field intensity onto the modulation signal to the coil and adjust a phase of the digital signal for demodulation based on the digital processing signal obtained in accordance with the superimposed signal.”

### REFERENCE SIGNS LIST

2 Magnetic sensor module (OPM), 4 Cell, 6 Pump laser light source (laser light source), 7 Photodiode (light detection unit), 8 Magnetic-field correction unit (coil), 101 Magnetic detection system, 103A, 103B Sensor unit, 105A, 105B Drive board (control unit), 113A Clock source, L Pump light (laser light)

What is claimed is:

1. A magnetic detection system comprising:
a cell in which an alkali metal is sealed;
a laser light source configured to emit laser light toward an inner side of the cell;
a light detection unit configured to detect the laser light having passed through the inner side of the cell and generate a light detection signal;
a coil configured to apply a magnetic field in a predetermined direction inside the cell; and
first and second magnetic sensor modules each having a control unit configured to supply a modulation signal having a modulation frequency to the coil, execute digital processing on a magnetic-field detection signal generated based on the light detection signal output from the light detection unit using a digital signal for demodulation corresponding to the modulation frequency, and generate a digital processing signal indicating a magnetic-field intensity inside the cell,
wherein the control unit of the second magnetic sensor module shares the modulation signal supplied from the control unit of the first magnetic sensor module to supply the modulation signal to the coil, and
uses a signal obtained by performing A/D conversion on the modulation signal supplied by the control unit of the first magnetic sensor module as the digital signal for demodulation.

2. The magnetic detection system according to claim 1, wherein the modulation signal supplied by the control unit of the first magnetic sensor module is generated by a clock source within the control unit.

3. The magnetic detection system according to claim 1 or 2, wherein control units of the first and second magnetic sensor modules perform a mixing process on the magnetic-field detection signal using the digital signal for demodulation.

4. The magnetic detection system according to claim 1, wherein the control unit of the second magnetic sensor module uses a signal obtained by performing A/D conversion on the modulation signal supplied by the control unit of the first magnetic sensor module and then shaping an A/D conversion result into a rectangular wave as the digital signal for demodulation.

5. The magnetic detection system according to claim 1, wherein control units of the first and second magnetic sensor modules adjust a phase of the digital signal for demodulation so that the magnetic-field intensity indicated by the digital processing signal becomes large.

6. The magnetic detection system according to claim 5, wherein the control units of the first and second magnetic sensor modules calculate the magnetic-field intensity based on two multiplication values obtained by multiplying the digital processing signal by two sine-wave signals having a target frequency of the magnetic-field intensity and having phases between which there is a 90-degree difference.

7. The magnetic detection system according to claim 5, wherein the control units of the first and second magnetic sensor modules supply a superimposed signal obtained by superimposing a reference signal having a target frequency of the magnetic-field intensity onto the modulation signal to the coil and adjust a phase of the digital signal for demodulation based on the digital processing signal obtained in accordance with the superimposed signal.
